(19) United States
(12) Patent Application Publication
(10) Pub. No.: US 2012/0156849 A1
(43) Pub. Date: Jun. 21, 2012

(54) METHOD FOR FABRICATING SEMICONDUCTOR DEVICE

(76) Inventor: Jae-Seon YU, Gyeonggi-do (KR)

(21) Appl. No.: 13/102,760

(22) Filed: May 6, 2011

(30) Foreign Application Priority Data
Dec. 17, 2010 (KR) 10-2010-0129802

(51) Int. Cl. H01L 21/02

(52) U.S. Cl. 438/381; 257/E21.008

(57) ABSTRACT

A method for fabricating a semiconductor device includes forming a storage node contact plug over a cell region of a substrate, forming a first inter-layer dielectric layer over the substrate, forming a first bit line over the first inter-layer dielectric layer in a peripheral region of the substrate, forming a second inter-layer dielectric layer over the first inter-layer dielectric layer, forming a second bit line over the second inter-layer dielectric layer, etching the second inter-layer dielectric layer to expose an upper surface of the storage node contact plug in the cell region, forming a capacitor contacting the storage node contact plug, forming a third inter-layer dielectric layer over the substrate having the capacitor formed thereon, forming a metal contact through the third inter-layer dielectric layer to contact the second bit line in the peripheral region, and forming a metal line contacting the metal contact over the third inter-layer dielectric layer.

### CROSS-REFERENCE TO RELATED APPLICATIONS

The present application claims priority of Korean Patent Application No. 10-2010-0129802, filed on Dec. 17, 2010, which is incorporated herein by reference in its entirety.

### BACKGROUND

1. Field of the Invention

Exemplary embodiments of the present invention relate to a semiconductor device fabrication method, and more particularly, to a method for fabricating a semiconductor device including metal contacts.

2. Description of the Related Art

Among the constituent elements of a semiconductor device, metal contacts are contacts for coupling metal lines with the structure formed under the metal lines, such as gates, bit lines, an upper electrode of a capacitor, and the like. The metal contacts are usually formed in peripheral regions, located outside cell regions.

Meanwhile, as semiconductor devices become more highly integrated, the area occupied by each constituent element decreases. In particular, as the area occupied by a capacitor in a Dynamic Random Access Memory (DRAM) device decreases, the height of the capacitor increases to secure sufficient capacitance. For this reason, the height of the metal contacts formed in the peripheral regions is increased so as to cause a contact-not-open phenomenon during the formation of contact holes, which is performed to form the metal contacts, or to increase the resistance of the metal contacts.

### SUMMARY

Exemplary embodiments of the present invention are directed to a method for forming a semiconductor device that may stably form metal contacts.

In accordance with an exemplary embodiment of the present invention, a method for fabricating a semiconductor device includes forming a storage node contact plug over a cell region of a substrate, forming a first inter-layer dielectric layer over the substrate, forming a first bit line over the first inter-layer dielectric layer in a peripheral region of the substrate, forming a second inter-layer dielectric layer over the first inter-layer dielectric layer, forming a second bit line over the second inter-layer dielectric layer in the peripheral region and electrically coupled to the first bit line, etching the second inter-layer dielectric layer to expose an upper surface of the storage node contact plug in the cell region, forming a capacitor in contact with the storage node contact plug in the cell region, forming a third inter-layer dielectric layer over the substrate having the capacitor formed thereon, forming a metal contact through the third inter-layer dielectric layer to contact the second bit line in the peripheral region, and forming a metal line in contact with the metal contact over the third inter-layer dielectric layer.

### BRIEF DESCRIPTION OF THE DRAWINGS

FIGS. 1A to 1F are cross-sectional views illustrating a method for fabricating a semiconductor device in accordance with a first exemplary embodiment of the present invention.

FIGS. 2A to 2D are cross-sectional views illustrating a method for fabricating a semiconductor device in accordance with a second exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate. The exemplary embodiments of the present invention provide a method for fabricating a semiconductor device that may stably form metal contacts coupling metal lines with a structure below the metal lines.

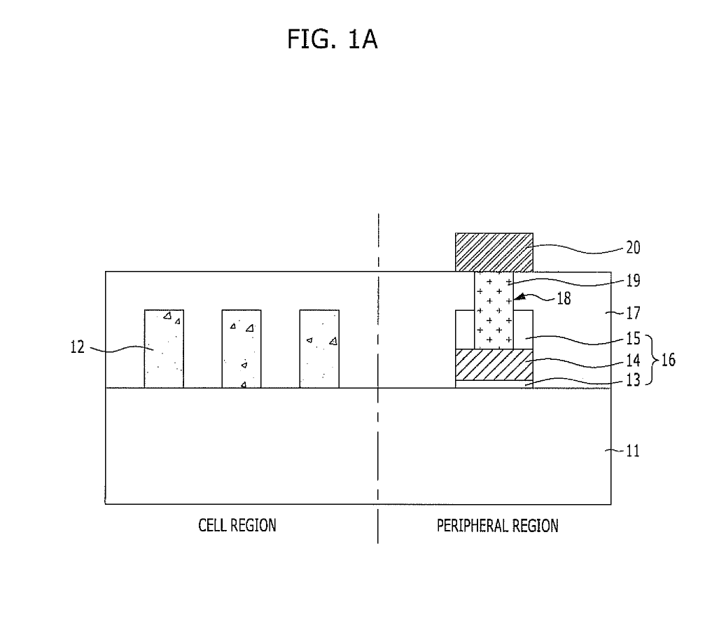

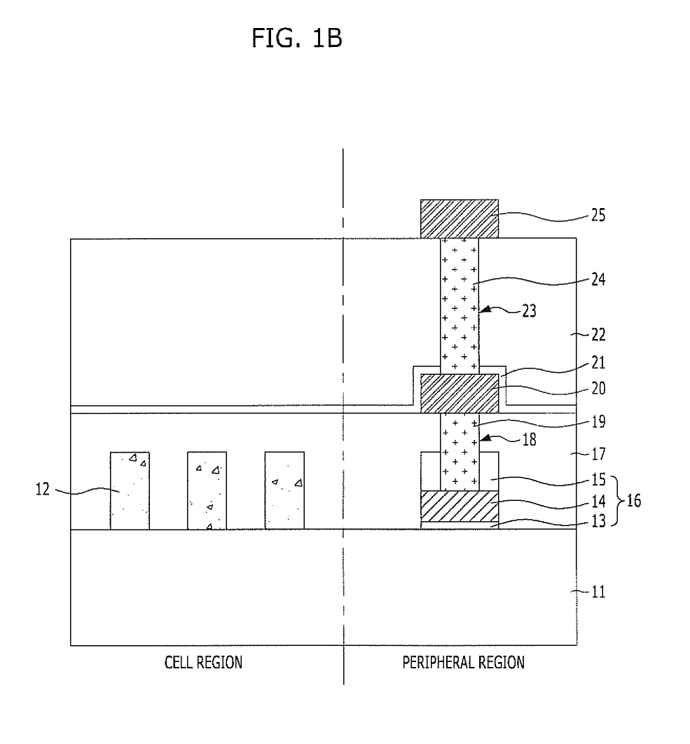

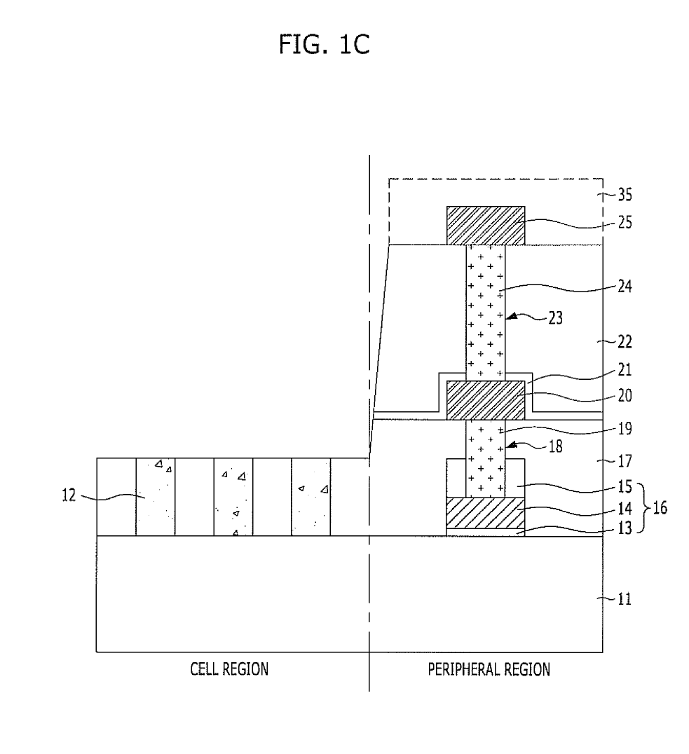

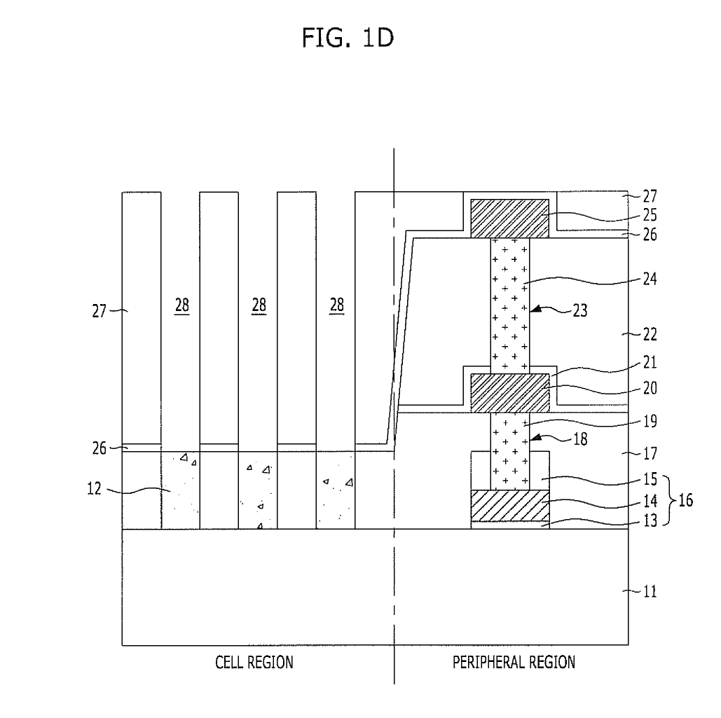

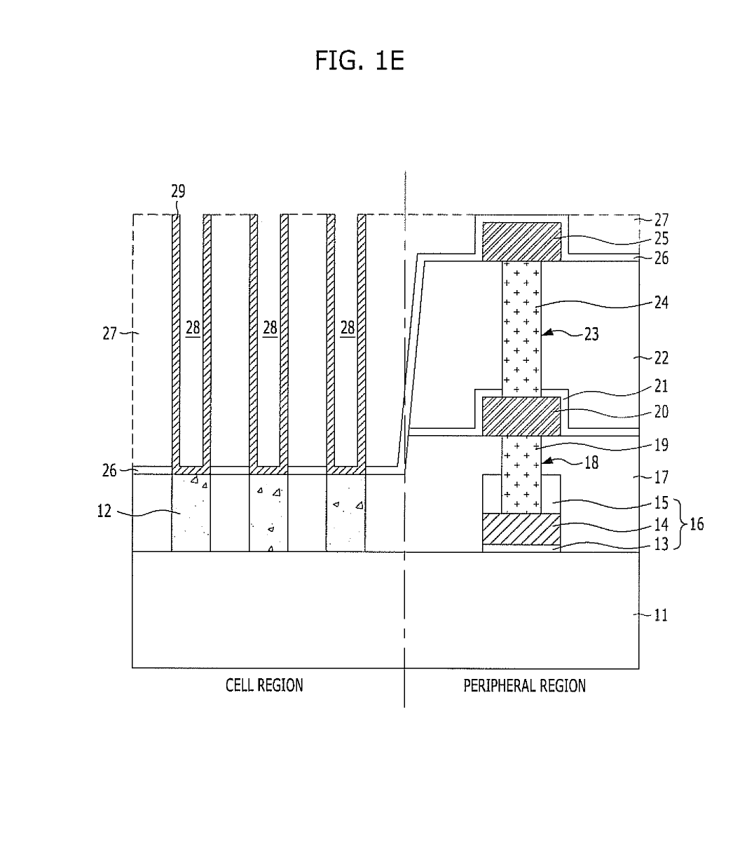

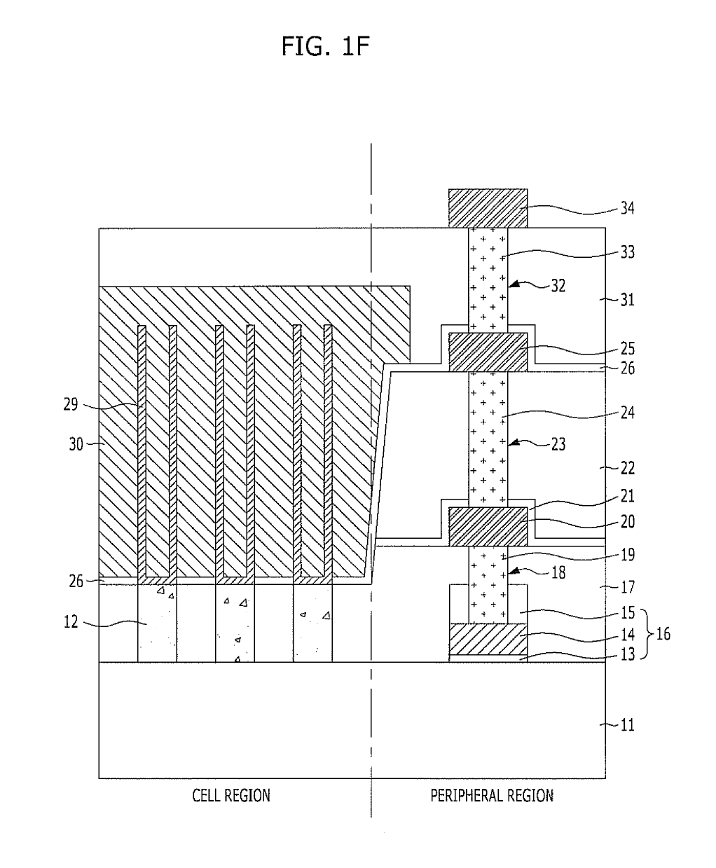

FIGS. 1A to 1F are cross-sectional views illustrating a method for fabricating a semiconductor device in accordance with a first exemplary embodiment of the present invention.

Referring to FIG. 1A, a substrate 11 includes a cell region and a peripheral region and the substrate 11 is provided with predetermined structures, such as an isolation layer and buried gates (not shown), Storage node contact plugs 12 are formed in the cell region over the substrate 11, while a peripheral gate 16 is formed in the peripheral region over the substrate 11. The peripheral gate 16 may be a stacked structure where a peripheral gate insulation layer 13, a peripheral gate electrode 14, and a peripheral gate hard mask layer 15 are sequentially stacked.

Subsequently, a first inter-layer dielectric layer 17 covering the storage node contact plugs 12 and the peripheral gate 16 is formed over the substrate 11. The first inter-layer dielectric layer 17 may be formed of one or more layers selected from the group consisting of an oxide layer, a nitride layer, and an oxynitride layer.

Subsequently, first contact holes 18 which expose the peripheral gate electrode 14 are formed by selectively etching the first inter-layer dielectric layer 17 of the peripheral region and the peripheral gate hard mask layer 15. Then, first bit line contact plugs 19 are formed by filling the first contact holes 18 with a conductive material.

Subsequently, first bit lines 20 are formed over the first inter-layer dielectric layer 17 in contact with the first bit line contact plugs 19.

Referring to FIG. 1B, a first etch stop layer 21 is formed along the surface of the substrate structure including the first bit lines 20. The first etch stop layer 21 is formed of a material having an etch selectivity with respect to the first inter-layer dielectric layer 17. For example, when the first inter-layer dielectric layer 17 is formed of an oxide, the first etch stop layer 21 may be formed of a nitride.

Subsequently, a second inter-layer dielectric layer 22 is formed over the first etch stop layer 21. The second inter-layer dielectric layer 22 may be formed of one or more layers selected from the group consisting of an oxide layer, a nitride layer, and an oxynitride layer. The second inter-layer dielectric layer 22 is formed of a material having an etch selectivity with respect to the first etch stop layer 21. For example, when the first etch stop layer 21 is formed of a nitride, the second inter-layer dielectric layer 22 may be formed of an oxide.

Subsequently, second contact holes 23 that expose the first bit lines 20 are formed by selectively etching the second inter-layer dielectric layer 22 of the peripheral region and the first etch stop layer 21. Then, second bit line contact plugs 24 are formed by filling the second contact holes 23 with a conductive material.

Subsequently, second bit lines 25 are formed over the second inter-layer dielectric layer 22 in contact with the second bit line contact plugs 24.

Referring to FIG. 1C, a hard mask pattern 35 which covers the peripheral region and exposes the cell region is formed over the second inter-layer dielectric layer 22. The hard mask pattern 35 may be formed using a cell open mask. The hard mask pattern 35 may be an amorphous carbon layer or a stacked layer, including a silicon-rich carbon layer and a silicon oxynitride (SION). Herein, the silicon oxynitride (SION) serves as an anti-reflection layer.

Subsequently, the upper surfaces of the storage node contact plugs 12 are exposed by using the hard mask pattern 35 as an etch barrier and partially etching the second inter-layer dielectric layer 22, the first etch stop layer 21, and the first inter-layer dielectric layer 17 of the cell region. Herein, the etch process may be an over-etch process that is performed in two steps. In the first step, etching is performed until the first etch stop layer 21 is reached. Then, in the second step, the first etch stop layer 21 and the first inter-layer dielectric layer 17 are partially etched until the storage node contact plugs 12 are exposed.

The etch process may be a dry etch process or a wet etch process, or a combination of a dry etch process and a wet etch process. In the case of a dry etch process, the etch process is performed using fluorocarbon gas (CₓF_{y}, 1≦x≧5, 1≦y≧8) or fluoromethane gas (CₓH_{y}F_{z}, 1≦x≧3, 1≦y≧4, 0≦z≧5). Also, to control the etch characteristics, e.g., etch selectivity and etch rate, one or more gases selected from the group consisting of argon (Ar), helium (He), xenon (Xe), oxygen (O₂), carbon monoxide (CO), carbonyl sulfide (COS), nitrogen (N₂), hydrogen (H₂), hydrogen bromide (HBr), chlorine (Cl₂), tetrachlorosilane (SiCl₄), sulfur hexafluoride (SF₆), and nitrogen trifluoride (NF₃) may be added to the fluorocarbon gas or the fluoromethane gas. In the case of a wet etch process, the etch process may be performed using a buffered oxide etchant (BOE) solution or a hydrogen fluoride (HF) solution.

After completing the etch process, the hard mask pattern 35 is removed.

Referring to FIG. 1D, a second etch stop layer 26 is formed along the surface of the substrate structure, after the hard mask pattern 35 is removed. Then, a mold layer 27 is formed over the second etch stop layer 26. The mold layer 27 may be one or more layers selected from the group consisting of an oxide layer, a nitride layer, and an oxynitride layer. The mold layer 27 is formed of a material having an etch selectivity with respect to the second etch stop layer 26. The mold layer 27 may be formed to be a flexible dielectric layer in consideration of the step height difference between the cell region and the peripheral region. The flexible dielectric layer may be formed of Baro-Phospho Silicate Glass (BPSG), Phospho Silicate Glass (PSG), Spin-On Dielectric (SOD), or silicon-rich carbon.

Subsequently, a planarization process is performed until the second etch stop layer 26 over the second bit lines 25 is exposed. Herein, the planarization process may be a Chemical Mechanical Polishing (CMP) process.

Subsequently, storage node holes 28 exposing the storage node contact plugs 12 are formed by selectively etching the mold layer 27 and the second etch stop layer 26 of the cell region. The etch process performed to form the storage node holes 28 is performed using a dry etch process. In particular, the dry etch process for forming the storage node holes 28 uses fluorocarbon gas (CₓF_{y}, 3≦x≧5, 5≦y≧8), e.g., C₃F₈, C₄F₆, C₄F₈, or C₅F₈, as a main etch gas so that the sidewalls of each storage node hole 28 have a vertical profile. Moreover, one or more gases selected from the group consisting of fluoromethane gas (CHₓF_{y}, 1≦x≧5, 1≦y≧8), e.g., CH₂F₂ and CH₃F, carbonyl sulfide (COS), oxygen (O₂), tetrachlorosilane (SiCl₄), and methane (CH₄), may be added to the main etch gas. Also, an inert gas, such as argon (Ar), xenon (Xe), and/or helium (He), may be added to increase the etch selectivity and stabilize plasma.

Meanwhile, since the height of the storage nodes is determined based on the height of the storage node holes 28, the height of the storage node holes 28 may be increased by additionally forming an insulation layer over the mold layer 27, after performing the planarization process onto the mold layer 27.

Referring to FIG. 1E, storage nodes 29 are formed inside of the storage node holes 28. The storage nodes 29 may be formed so that they are a cylindrical type (i.e., having a hollow center) or a pillar type (i.e., having a solid center). Here, as shown in the cross-sectional view of FIG. 1E, the storage nodes 29 are a cylindrical type.

Subsequently, the mold layer 27 is removed by performing a wet dip out process. The wet dip out may be performed using a BOE solution or fluoride solution. The second etch stop layer 26 may protect the lower structure from being damaged in the course of the wet dip out process.

Referring to FIG. 1F, a dielectric layer (not shown) may be formed on the surfaces of the storage nodes 29, and then a plate electrode 30 covering the storage nodes 29 and filling the space between the storage nodes 29 is formed. As a result, capacitors are formed in the cell region.

Subsequently, a third inter-layer dielectric layer 31 is formed over the substrate 11, having the plate electrode 30 formed thereon. The third inter-layer dielectric layer 31 may be formed of one or more materials selected from the group consisting of an oxide, a nitride, and an oxynitride.

Subsequently, third contact holes 32 exposing the second bit lines 25 are formed by selectively etching the third inter-layer dielectric layer 31 and the second etch stop layer 26 in the peripheral region. Then, metal contacts 33 are formed by filling the third contact holes 32 with a conductive material.

Subsequently, metal lines 34 are formed over the third inter-layer dielectric layer 31 in contact with the metal contacts 33.

The method for fabricating a semiconductor device in accordance with the first exemplary embodiment of the present invention may prevent a contact-not-open phenomenon from occurring or prevent the resistance of the metal contacts 33 from being increased by forming the first bit lines 20 and the second bit lines 25 in a double-layer structure in the peripheral region so as to decrease the height of the third contact holes 32 used to form the metal contacts 33. Also, it is possible to decrease the procedural difficulty of the process for forming the third contact holes 32 and improve a process error margin. Herein, according to conventional technology, the contact-not-open phenomenon may occur or the resistance of the metal contacts may increase because contact holes for forming the metal contacts 33 are formed by etching an inter-layer dielectric layer to a depth equal to the height of the storage nodes 29 in a single step. Also, in the conventional technology, the procedural difficulty is high due to the high aspect ratio of the contact holes, and therefore, it is hard to secure a desirable process margin.

In accordance with an exemplary embodiment of the present invention, because the bit lines formed in the peripheral region have a double-layer structure, the bit lines may be more easily formed in the peripheral region although the space where the bit lines are to be formed is reduced.

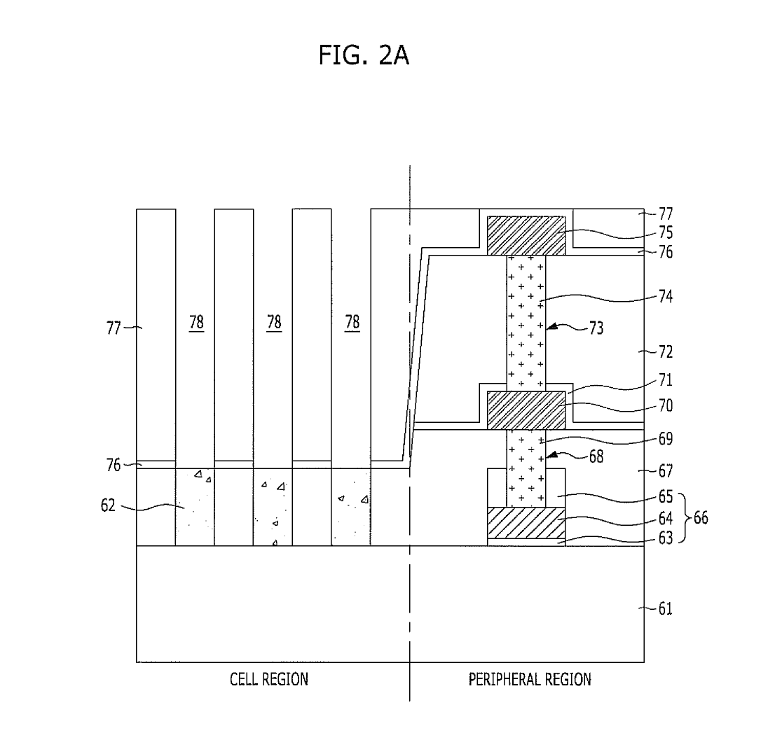

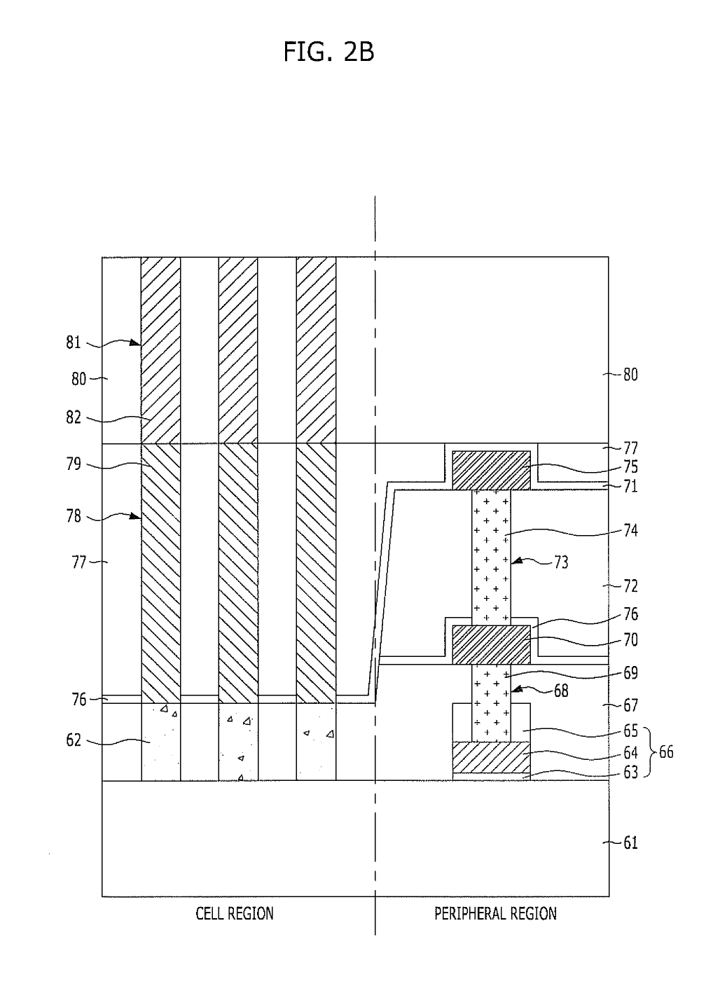

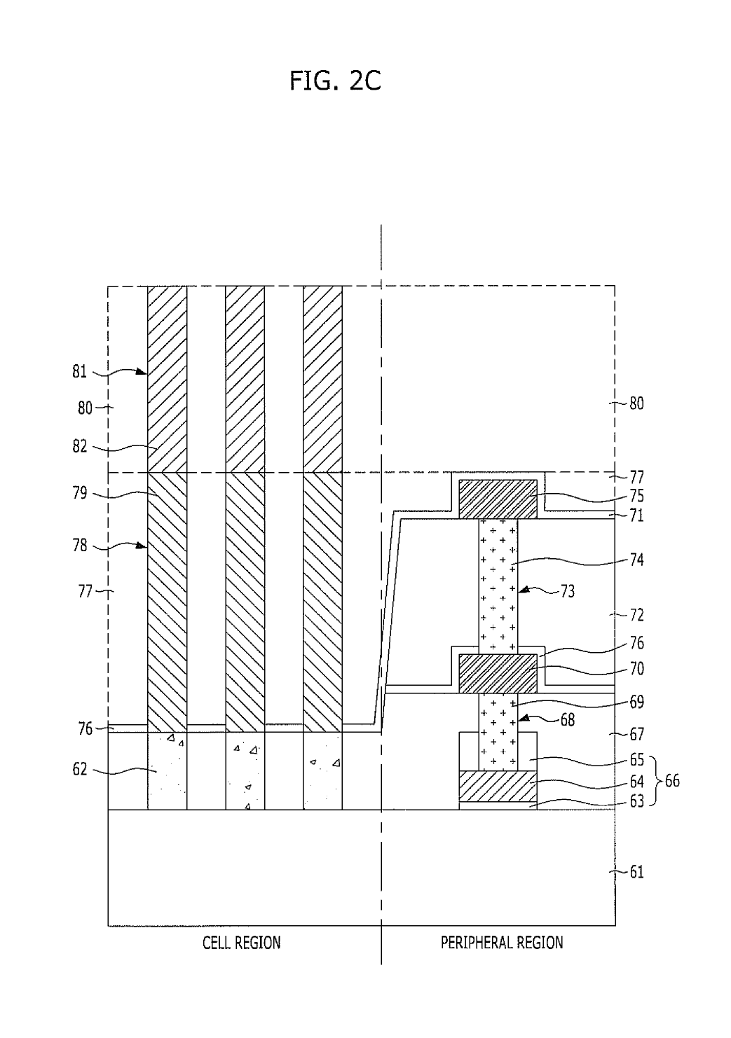

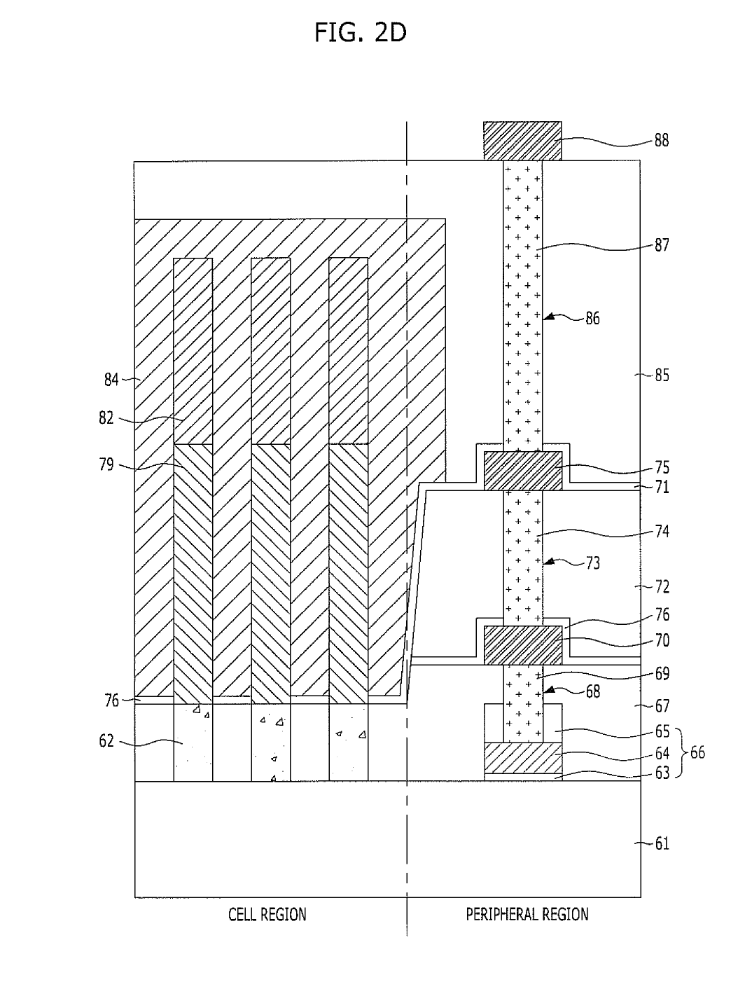

FIGS. 2A to 2D are cross-sectional views illustrating a method for fabricating a semiconductor device in accordance with a second exemplary embodiment of the present invention.

Referring to FIG. 2A, a substrate 61 having a cell region and a peripheral region and including predetermined structures, such as an isolation layer and buried gates (not shown), is provided in the same way that substrate 11 was provided as described in FIGS. 1A to 1D. Storage node contact plugs 62, a first mold layer 77, and first storage node holes 78 are formed in the cell region over the substrate 61. Meanwhile, peripheral gates 66, first bit lines 70, and second bit lines 75 are formed in the peripheral region over the substrate 61.

Herein, reference numeral ‘63’ denotes a peripheral gate insulation layer, and reference numeral ‘64’ denotes a peripheral gate electrode. Reference numeral ‘65’ denotes a peripheral gate hard mask layer, and reference numeral ‘67’ denotes a first inter-layer dielectric layer. Reference numeral ‘68’ denotes first contact holes, and reference numeral ‘69’ denotes first bit line contact plugs. Reference numeral ‘71 ’ denotes a second etch stop layer, and reference numeral ‘72 ’ denotes a second inter-layer dielectric layer. Reference numeral ‘73 ’ denotes second contact holes, and reference numeral ‘74 ’ denotes second bit line contact plugs. Reference numeral ‘76 ’ denotes a first etch stop layer.

Referring to FIG. 2B, first storage nodes 79 are formed inside of the first storage node holes 78, respectively. Herein, the first storage nodes 79 are a pillar type.

Subsequently, a second mold layer 80 is formed over the first mold layer 77. The second mold layer 80 may be formed of the same material as the first mold layer 77.

Subsequently, second storage node holes 81 exposing the first storage nodes 79 are formed by selectively etching the second mold layer 80. Then, second storage nodes 82 are formed inside of the second storage node holes 81. Herein, the second storage nodes 82 may be a pillar type or a cylindrical type.

The etch process for forming the second storage node holes 81 uses a fluorocarbon gas (CₓF_{y}, 3≦x≧5, 5≦y≧8), e.g., C₃F₈, C₄F₆, C₄F₈, or C₅F₈, as a main etch gas so that the sidewalls of each of the second storage node holes 81 have a vertical profile. Moreover, one or more gases selected from the group consisting of fluoromethane gas (CHₓF_{y}, 1≦x≧5, 1≦y≧8), e.g., CH₂F₂ and CH₃F, carbonyl sulfide (COS), oxygen (O₂), tetrachlorosilane (SiCl₄), and methane (CH₄), may be added to the main etch gas. Also, an inert gas such as argon (Ar), xenon (Xe) and/or helium (He) may be added to increase the etch selectivity and stabilize plasma.

Referring to FIG. 2C, the first and second mold layers 77 and 80 are removed by performing a wet dip out process. The wet dip out may be performed using a BOE solution or fluoride solution. The second etch stop layer 71 may protect structures beneath it from being damaged in the course of the wet dip out process. Once the first and second mold layers 77 and 80 are removed, a dielectric layer (not shown) is formed on the surfaces of the first storage nodes 79.

Then, referring to FIG. 2D, a plate electrode 84 is formed to fill the space between and cover the first storage nodes 79 and the second storage nodes 82. As a result, a capacitor having a greater capacitance than that of the first exemplary embodiment of the present invention may be formed in the cell region.

Subsequently, a third inter-layer dielectric layer 85 is formed over the substrate 61, having the plate electrode 84 formed thereon. The third inter-layer dielectric layer 85 may be formed of one or more materials selected from the group consisting of an oxide, a nitride, and an oxynitride.

Subsequently, third contact holes 86 exposing the second bit lines 75 are formed by selectively etching the third inter-layer dielectric layer 85 and the second etch stop layer 76 in the peripheral region. Then, metal contacts 87 are formed by filling the third contact holes 86 with a conductive material.

Subsequently, metal lines 88 are formed over the third inter-layer dielectric layer 85 in contact with the metal contacts 87.

According to the method for fabricating a semiconductor device in accordance with the second exemplary embodiment of the present invention, the height of the third contact holes 86 for forming the metal contacts 87 may be decreased by forming a double-layer structure, having the first bit lines 70 and the second bit lines 75, in the peripheral region. Also, in order to secure the level of capacitance required by the semiconductor device within a limited area, the height of the storage nodes is increased by forming the storage nodes in two steps (i.e., by forming the first storage nodes 79 and the second storage nodes 82). Moreover, in accordance with the second exemplary embodiment described above, the height of the storage nodes can be increased although the height of the third contact holes 86 for forming the metal contacts 87 may be decreased by adjusting the height of the first inter-layer dielectric layer 67 and the second inter-layer dielectric layer 72. By performing the method of the second exemplary embodiment, it is possible to prevent a contact-not-open phenomenon from occurring or prevent the resistance of the metal contacts 87 from increasing when the third contact holes 86 are formed. In addition, the procedural difficulty of the process for forming the third contact holes 86 may be decreased and the process error margin may be improved.

Also, since the bit lines of the peripheral region form a double-layer structure, the bit lines of the peripheral region may be formed more easily although the integration degree of the semiconductor device increases thereby reducing the space where the bit lines are to be formed.

According to the technology of the present invention, the height of metal contacts may be decreased by forming first and second bit lines in a double-layer structure in peripheral regions. Also, to secure a required level of capacitance in a limited area of a semiconductor device, the height of the metal contacts may be decreased by adjusting the height of the first and second inter-layer dielectric layers, while the height of capacitors, that is, the height of storage nodes, may be increased. Through the processes described above, it is possible to prevent a contact-not-open phenomenon from occurring during the formation of contact holes, which is performed to form the metal contacts, or to prevent the resistance of the metal contacts from increasing. Moreover, the procedural difficulty for the process for forming contact holes is decreased, and a process error margin may be improved.

In addition, since the bit lines in the peripheral regions of a semiconductor device form a double-layer structure, although the space where the bit lines are to be formed is decreased due to an increase in the integration degree of the semiconductor device, the bits lines may be more easily formed in the peripheral regions of the semiconductor device.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a storage node contact plug over a cell region of a substrate;
forming a first inter-layer dielectric layer over the substrate;
forming a first bit line over the first inter-layer dielectric layer in a peripheral region of the substrate;
forming a second inter-layer dielectric layer over the first inter-layer dielectric layer;
forming a second bit line over the second inter-layer dielectric layer in the peripheral region and electrically coupled to the first bit line;
etching the second inter-layer dielectric layer to expose an upper surface of the storage node contact plug in the cell region;
forming a capacitor in contact with the storage node contact plug in the cell region;
forming a third inter-layer dielectric layer over the substrate having the capacitor formed thereon;
forming a metal contact through the third inter-layer dielectric layer to contact the second bit line in the peripheral region; and
forming a metal line in contact with the metal contact over the third inter-layer dielectric layer.

2. The method of claim 1, wherein the forming of the metal contact comprises:
forming a contact hole exposing the second bit line by selectively etching the third inter-layer dielectric layer in the peripheral region; and
forming the metal contact by filling the contact hole with a conductive material.

3. The method of claim 1, wherein the forming of the second bit line comprises:
forming a bit line contact plug through the second inter-layer dielectric layer to contact the first bit line; and
forming the second bit line over the second inter-layer dielectric layer and in contact with the bit line contact plug.

4. The method of claim 1, wherein the upper surface of the storage node contact plug is exposed through a dry etch process, a wet etch process, or a combination of a dry etch process and a wet etch process.

5. The method of claim 1, wherein the forming of the capacitor comprises:
forming an etch stop layer over the substrate having the storage node contact plug formed in the cell region;
forming a mold layer over the etch stop layer;
performing a planarization process until a portion of the etch stop layer is exposed;
forming a storage node hole exposing the upper surface of the storage node contact plug by selectively etching the mold layer and the etch stop layer;
forming a storage node inside the storage node hole;
removing the mold layer;
forming a dielectric layer along the surface of the storage node; and
forming a plate electrode covering the storage node.

6. The method of claim 5, wherein the selective etching used in the forming of the storage node hole is an etch process that uses fluorocarbon gas.

7. The method of claim 6, wherein in addition to the fluorocarbon gas, the etch process uses one or more gases selected from the group consisting of fluoromethane gas, carbonyl sulfide, oxygen, tetrachlorosilane, and methane.

8. The method of claim 7, wherein the etch process further uses an inert gas.

9. The method of claim 5, wherein the storage node is a cylindrical type or a pillar type.

10. The method of claim 5, wherein the mold layer is a flexible dielectric layer.

11. The method of claim 1, wherein the forming of the capacitor comprises:
forming an etch stop layer over the substrate having the storage node contact plug formed in the cell region;
forming a first mold layer over the etch stop layer;
performing a planarization process until a portion of the etch stop layer is exposed;
forming a first storage node hole exposing the upper surface of the storage node contact plug by selectively etching the first mold layer and the etch stop layer;
forming a first storage node inside the storage node hole;
forming a second mold layer over the first mold layer;
forming a second storage node hole exposing an upper surface of the first storage node by selectively etching the second mold layer;
forming a second storage node inside the second storage node hole;
removing the first mold layer and the second mold layer;
forming a dielectric layer along the surface of the first storage node and the second storage node; and
forming a plate electrode covering the first storage node and the second storage node.

12. The method of claim 11, wherein the first storage node is a pillar type.

13. The method of claim 11, wherein the second storage node is a pillar type or a cylindrical type.

14. The method of claim 11, wherein the first mold layer and the second mold layer are formed of the same material.

15. The method of claim 11, wherein the first mold layer and the second mold layer comprise a flexible dielectric layer.

16. The method of claim 1, further comprising:
forming a first etch stop layer between forming the first inter-layer dielectric layer and forming the second inter-layer dielectric layer.

17. The method of claim 1, wherein the etching of the second inter-layer dielectric layer comprises:
forming a mask in the peripheral region; and
etching the second inter-layer dielectric layer.

18. The method of claim 17, wherein the mask protects the second bit line in the peripheral region from being damaged by the etching of the second inter-layer dielectric layer.

19. The method of claim 1, further comprising:
forming a peripheral gate over the substrate in the peripheral region; and
forming a first bit line contact plug,
wherein the peripheral gate is electrically connected to the first bit line via the first bit line contact plug.
